(19) United States
(12) Patent Application Publication
(10) Pub. No.: US 2026/0310835 A1
(43) Pub. Date: Oct. 8, 2026

(54) SYSTEM AND METHOD FOR GENERATING ARCHITECTURAL FORM

(71) Applicant: Alexander Loyer Hughes, New York, NY (US)

(72) Inventor: Alexander Loyer Hughes, New York, NY (US)

(21) Appl. No.: 19/170,897

(22) Filed: Apr. 4, 2025

(51) Int. Cl. G06F 30/10

(52) U.S. Cl. CPC G06F 30/10

(57) ABSTRACT

A computer-implemented method for generating architectural forms, including: receiving one or more musical notes, converting the one or more musical notes into corresponding digital audio signals, identifying a tonal interval, wherein the tonal interval is indicative of a difference between two digital audio signals associated with the one or more musical notes, executing, using a computer, a command function based on, in part, the identified tonal interval and at least one input parameter to generate at least one spatial feature, mapping the at least one spatial feature to an attribute of an spatial form, constructing the spatial form based on the mapped attribute of the spatial form, mapping the mapped attribute of the spatial form to at least one architectural feature, mapping the at least one architectural feature to an attribute of an architectural form and constructing the architectural form based on the mapped attribute of the architectural form.

### FIELD OF THE DISCLOSURE

The present disclosure relates to devices/systems and methods for processing of music or audio data in electronic form to generate two-dimensional or three-dimensional renderings. More particularly, the present disclosure relates to creating two or three-dimensional architectural forms derived from audio data.

### BACKGROUND

Music digitalizers and visualizers have been used to convert electronic audio data or music into visual representations displayed on computer screens. Similarly, computer-aided design (CAD) software (e.g., Autodesk Revit) and digital sketching tools have enabled the architectural visualization of concepts. However, these conventional technologies fall short in allowing musicians to translate their musical expressions, captured in audio data, into tangible architectural forms or designs. Such tangible architectural forms or designs may be computer modeled or constructed physically. Therefore, there is still a need and desire to have devices/systems and methods that address the above limitations.

### BRIEF SUMMARY OF THE DISCLOSURE

One embodiment of the disclosure is directed to a method of generating architectural forms comprising: receiving one or more musical notes; converting the received one or more musical notes into corresponding digital audio signals; identifying a tonal interval, wherein the tonal interval is indicative of a difference between two digital audio signals associated with the one or more musical notes; executing, using a computer, a command function based on, in part, the identified tonal interval and at least one input parameter to generate at least one spatial feature; mapping the at least one spatial feature to an attribute of an spatial form; constructing the spatial form based on the mapped attribute of the spatial form; mapping the mapped attribute of the spatial form to at least one architectural feature; mapping the at least one architectural feature to an attribute of an architectural form; and constructing the architectural form based on the mapped attribute of the architectural form.

Another embodiment is directed to the method, wherein identifying the tonal interval further comprises: designating a first digital audio signal from the corresponding digital audio signals as a root note; applying a circle of fifths function with the root note as input to process the corresponding digital audio signals; and determining the one or more tonal intervals based on the processed corresponding digital audio signals.

Another embodiment is directed to the method, wherein the least one input parameter is specified to determine one or more sizes of a set of architectural features. Another embodiment is directed to the method, wherein the least one input parameter is specified to determine one or more colors represent a set of architectural features. Another embodiment is directed to the method, wherein the least one input parameter is specified to determine a set of architectural features, the set of architectural features are based on Pythagorean triples. Another embodiment is directed to the method, wherein the least one input parameter is specified to determine a set of architectural features, the set of architectural features are based on a 3D polyform seed. Another embodiment is directed to the method, wherein executing, using a computer, the command function based on, in part, the identified tonal interval and the at least one input parameter to generate the at least one spatial feature further comprises: transforming the identified tonal interval into at least one corresponding Pythagorean triple; generating an initial triangle based on the at least one corresponding Pythagorean triple; constructing a Pythagoras tree from the initial triangle by recursively applying geometric transformations at one or more scales of the Pythagoras tree, the geometric transformations include: generating squares that circumscribe the initial triangle at a first scale of the Pythagoras tree; and replicating the squares that circumscribe the initial triangle and the initial triangle at other scales of the Pythagoras tree to create additional squares that circumscribe the corresponding additional triangles; and generating the at least one spatial feature based on a resulting geometric structure of the Pythagoras tree.

One embodiment of the disclosure is directed to a computer-implemented method of generating architectural forms comprising: receiving one or more musical notes; converting the received one or more musical notes into corresponding digital audio signals; identifying a tonal interval, wherein the tonal interval is indicative of a difference between two or more digital audio signals associated with the one or more musical notes; executing, using a computer, a command function based on, in part, the identified tonal interval and at least one input parameter to generate at least one spatial feature; mapping the at least one spatial feature to an attribute of an spatial form; constructing the spatial form based on the mapped attribute of the spatial form; mapping the mapped attribute of the spatial form to at least one architectural feature; mapping the at least one architectural feature to an attribute of an architectural form; and constructing the architectural form based on the mapped attribute of the architectural form.

Another embodiment is directed to the computer-implemented method, wherein identifying the tonal interval further comprises: designating a first digital audio signal from the corresponding digital audio signals as a root note; applying a circle of fifths function with the root note as input to process the corresponding digital audio signals; and determining the one or more tonal intervals based on the processed corresponding digital audio signals.

Another embodiment is directed to the computer-implemented method, wherein the least one input parameter is specified to determine one or more sizes of a set of architectural features. Another embodiment is directed to the method, wherein the least one input parameter is specified to determine one or more colors represent a set of architectural features. Another embodiment is directed to the method, wherein the least one input parameter is specified to determine a set of architectural features, the set of architectural features are based on Pythagorean triples. Another embodiment is directed to the method, wherein the least one input parameter is specified to determine a set of architectural features, the set of architectural features are based on a 3D polyform seed. Another embodiment is directed to the method, wherein executing, using a computer, the command function based on, in part, the identified tonal interval and the at least one input parameter to generate the at least one spatial feature further comprises: transforming the identified tonal interval into at least one corresponding Pythagorean triple; generating an initial triangle based on the at least one corresponding Pythagorean triple; constructing a Pythagoras tree from the initial triangle by recursively applying geometric transformations at one or more scales of the Pythagoras tree, the geometric transformations include: generating squares that circumscribe the initial triangle at a first scale of the Pythagoras tree; and replicating the squares that circumscribe the initial triangle and the initial triangle at other scales of the Pythagoras tree to create additional squares that circumscribe the corresponding additional triangles; and generating the at least one spatial feature based on a resulting geometric structure of the Pythagoras tree.

### BRIEF DESCRIPTION OF THE SEVERAL VIEWS OF THE DRAWINGS

The following detailed description of the exemplary embodiments of the subject disclosure will be better understood when read in conjunction with the appended drawings. For the purpose of illustrating the present disclosure, there are shown in the drawings exemplary embodiments. It should be understood, however, that the subject disclosure is not limited to the precise arrangements and instrumentalities shown.

In the drawings:

FIG. 1 illustrates an exemplary representation of an architectural form rendering in accordance with the subject disclosure;

FIG. 2 illustrates an architectural form generation system in accordance with an exemplary embodiment of the subject disclosure;

FIG. 3 illustrates a flow chart of a method for generating an architectural form in accordance with an exemplary embodiment of the subject disclosure;

FIG. 4 illustrates a flow chart of a method for generating an architectural form using music in accordance with an exemplary embodiment of the subject disclosure;

FIG. 5 illustrates an exemplary system that may be used to generate a three-dimensional rendering of musical notes;

FIG. 6 illustrates a flow chart of a method for generating an architectural rendering in accordance with an exemplary embodiment of the subject disclosure;

FIG. 7 illustrates a flow chart of a method for generating an architectural rendering in accordance with an exemplary embodiment of the subject disclosure; and

FIG. 8 illustrates a flow chart of a method for generating an architectural form using music in accordance with an exemplary embodiment of the subject disclosure.

### DETAILED DESCRIPTION

Reference will now be made in detail to the various exemplary embodiments of the subject disclosure illustrated in the accompanying drawings. Wherever possible, the same or like reference numbers will be used throughout the drawings to refer to the same or like features. It should be noted that the drawings are in simplified form and are not necessarily drawn to precise scale. Certain terminology is used in the following description for convenience only and is not limiting. Directional terms such as top, bottom, left, right, above, below and diagonal, are used with respect to the accompanying drawings. The term “distal” shall mean away from the center of a body. The term “proximal” shall mean closer towards the center of a body and/or away from the “distal” end. The words “inwardly” and “outwardly” refer to directions toward and away from, respectively, the geometric center of the identified element and designated parts thereof. Such directional terms used in conjunction with the following description of the drawings should not be construed to limit the scope of the subject disclosure in any manner not explicitly set forth. Additionally, the term “a,” as used in the specification, means “at least one.” The terminology includes the words above specifically mentioned, derivatives thereof, and words of similar import.

“About” as used herein when referring to a measurable value such as an amount, a temporal duration, and the like, is meant to encompass variations of ±20%, ±10%, ±5%, ±1%, or ±0.1% from the specified value, as such variations are appropriate.

“Substantially” as used herein shall mean considerable in extent, largely but not wholly that which is specified, or an appropriate variation therefrom as is acceptable within the field of art. “Exemplary” as used herein shall mean serving as an example.

Throughout this disclosure, various aspects of the subject disclosure can be presented in a range format. It should be understood that the description in range format is merely for convenience and brevity and should not be construed as an inflexible limitation on the scope of the subject disclosure. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, and 6. This applies regardless of the breadth of the range.

The following term definitions and interchangeable terms are used throughout the subject disclosure.
The term “3D polyform seed” refers to a geometric structure or configuration used as the base or starting point for constructing more complex spatial and/or architectural forms.
The term “architectural feature” is a characteristic or attribute of an architectural form. The term “architectural feature” may encompass elements such as shapes, polygons, planes, layers, dimensions, orientations, styles, textures, colors (e.g., palette and hues) or decorative details that define and contribute to the identity and functionality of the architectural form and/or its individual elements (e.g., walls, windows, doors, roofs and floors). Examples of “architectural features” include curvature of arches, detailing on columns, dimensions of windows and design of rooflines.
The term “architectural form” refers to the shape(s), structure(s), construct(s) or configuration(s) of a building or constructed space, including its physical and spatial components, which is (are) derived from one or more spatial forms. The term “architectural form” may encompass the arrangement and relationship of architectural features and attributes, such as walls, windows, doors, roofs, and floors, as well as the way these features interact to create spaces. The “architectural form” can be visualized in 3D or 2D software (e.g., Autodesk Revit, Rhinoceros 3D, Rhinoceros, Rhino, or Rhino3D), allowing for two-dimensional or a three-dimensional representations or renderings (e.g., digital models). The “architectural form” may be translated into one or more physical structures via construction or 3D printing, or represented through technical outputs or documentation such as floor plans, ceiling plans, structural plans and elevations, i.e., architectural plans (e.g., in formats like PDF, DWG (AutoCAD), DWF/DWFx, or image files like JPEG, PNG, and TIFF).
The term “attribute of a spatial form” is a specific property, characteristic, or quality that defines or influences the design, structure, or function of the spatial form. “Attributes of a spatial form” can include measurable aspects, such as height, width, depth, or spatial orientation, as well as qualitative aspects, such as material, texture, color, or style. “Spatial features” may be assigned, associated, or mapped to “attributes of the spatial form.”
The term “attribute of an architectural form” is a specific property, characteristic, or quality that defines or influences the design, structure, or function of the architectural form. “Attributes of an architectural form” can include measurable aspects, such as height, width, depth, or spatial orientation, as well as qualitative aspects, such as material, texture, color, or style. “Architectural features” may be assigned, associated, or mapped to “attributes of the architectural form.”
The term “command function” refers to a computational instruction executed by a computer to perform a specific task based on one or more identified tonal intervals between musical notes. For example, a “command function” may process the tonal intervals to generate at least one spatial feature and/or architectural feature.
The term “geometric transformation” denotes a mathematical operation that may modify the position, size, shape, or orientation of a geometric object, architectural form, architectural feature, Pythagoras tree, spatial feature, spatial form, or an attribute of an architectural or a spatial form. Geometric Transformations” may involve various operations such as translation (shifting an object or polygon without changing its shape), rotation (turning an object around a fixed point), scaling (increasing or decreasing the size while maintaining proportions), reflection (creating a mirror image across an axis), replication, and shearing (distorting an object while keeping its basic structure).
The term “musical pitch mapping” refers to the process of converting numerical values, such as OSC (Open Sound Control) values, into corresponding musical notes or pitches on a defined musical scale (or vice versa).
The term “Pythagorean triple” denotes a set of three positive integers (a, b, c) that satisfy the equation a²+b²=c², representing the side lengths of a right triangle.
The term “root note” is the starting point or reference musical note that serves as the base for mapping a sequence of musical notes onto a musical scale or key.
The term “spatial form” refers to vector(s), vector data, or geometric data (e.g., shapes or polygons) that are directly or indirectly derived from musical notes and represent the shape, geometric structure, or configuration of a geometric building, structure or space. The “spatial form” can be visualized in 3D or 2D software (e.g., Autodesk Maya or Grasshopper 3D), allowing for two-dimensional or a three-dimensional representations or renderings.
The term “tonal interval” refers to the difference in pitch between two musical notes. The “tonal interval” may be expressed in terms of a specific musical distance (e.g., a “perfect fifth” or “major third” or “three semitones”), a frequency, a frequency difference, or as a frequency ratio (e.g., a 3:2 ratio for a “perfect fifth”). The term “tonal interval” encompasses both the size of the interval (in terms of pitch) and its mathematical relationship in terms of frequency.
The term “spatial feature” is a characteristic or attribute of a spatial form. The term “spatial feature” may encompass elements such as shapes, polygons, planes, layers, dimensions, three-dimensional points (vertices and edges), orientations, styles, textures, colors (e.g., palette and hues) or decorative details that define and contribute to the identity and functionality of the spatial form and/or its individual elements. Examples of “spatial features” include Non-Uniform Rational B-Splines (NURBS), polygons, colors, shapes or surfaces.
The term “architectural form” may be used interchangeably with terms “architectural form rendering” and “architectural form construct.”
The term “command function” may be used interchangeably with the term “command.”
The term “Geometric Transformation” may be used interchangeably with term “transformation” or “transform.”
The term “modeling parameter” may be used interchangeably with terms “input parameter,” “user-defined parameter” or “parameter.”
The term “Pythagorean tree” may be used interchangeably with the term “Pythagoras tree.”
The term “Pythagorean triple” may be used interchangeably with terms “Pythagoras triple” or “triple.”

Furthermore, the described features, advantages, and characteristics of the exemplary embodiments of the subject disclosure may be combined in any suitable manner in one or more embodiments. One skilled in the relevant art will recognize, in light of the description herein, that the present disclosure can be practiced without one or more of the specific features or advantages of a particular exemplary embodiment. In other instances, additional features and advantages may be recognized in certain embodiments that may not be present in all exemplary embodiments of the subject disclosure.

The subject architectural form generation system uses digital audio discretized signals, which may be an input e.g., input from a source of musical notes that originate from musical instruments, or an electronic representations of musical notes, such as from a synthesizer, or a musical composition, or musical score or electrical or waveform signal input that corresponds to one or more musical notes of a musical instrument. The subject architectural form generation system uses these inputs to determine a modeling root value and identify relevant spatial features, which together generate an initial spatial form. The subject architectural form generation system may then apply optional geometric transforms to this form and output the resulting spatial and/or architectural form. Spatial and/or architectural features are generated based on the spatial features of the resulting spatial form, and the final architectural form is output, reflecting the generated spatial and/or architectural features.

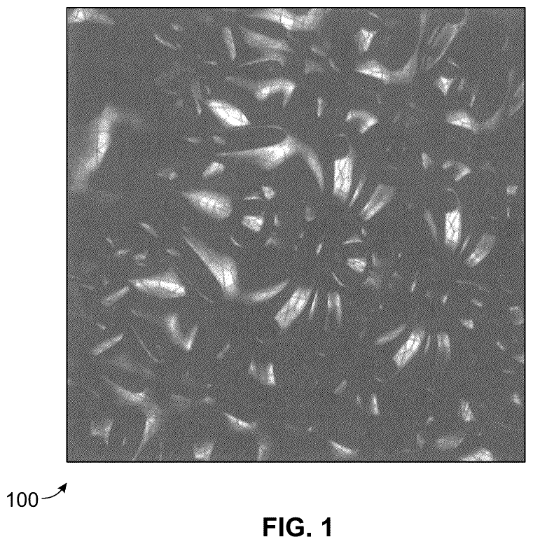

Referring now to the drawings, FIG. 1 illustrates an exemplary visualization of a spatial form or an architectural form, 100 generated in accordance with exemplary embodiments of the architectural form generation systems and methods. Although an exemplary embodiment of the subject system shows and describes the spatial form or architectural form, as a two-dimensional representation, the spatial form and/or architectural form, can also be a three-dimensional spatial form and/or architectural form with corresponding three-dimensional geometric transforms applied (for example, by including transforms applied along a z-axis).

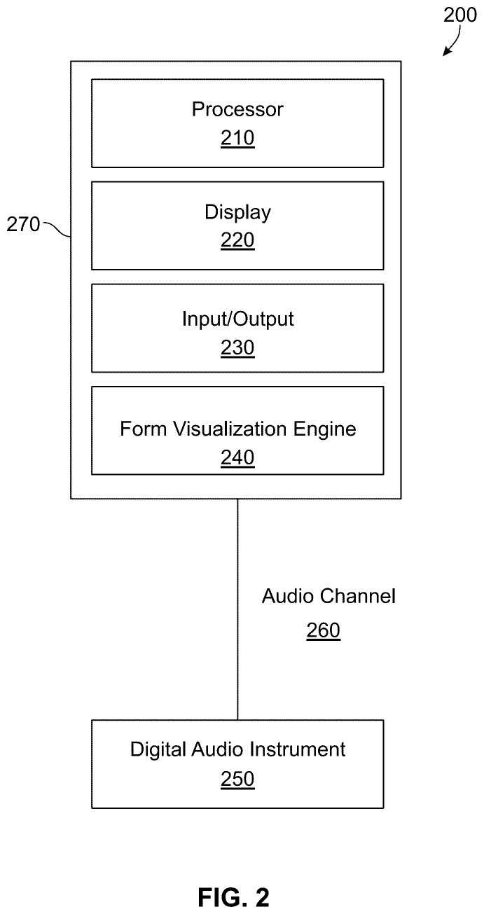

In some embodiments the architectural form generation system 200 constructs the spatial form (or architectural form derived from the spatial form) using digital audio discretized signals, e.g., input from a digital audio instrument 250 (FIG. 2) such as an electronic musical instrument, where the digital audio discretized signals represent musical notes of a musical instrument, to determine a modeling root value and/or one or more spatial features (or architectural features). Embodiments may be configured to generate an initial spatial form based on the modeling root value and/or spatial features, apply desired transforms, and display and/or output the resulting spatial form. Examples of spatial features can include a color, plane, and layer that the subject system determines based on musical notes identified from the digital audio discretized signals.

FIG. 2 illustrates an architectural form generation system 200 in accordance with an exemplary embodiment of the disclosure. The architectural form generation system 200 includes a computer 270 having a processor 210 in communication with a display 220, an input/output interface 230, and a form visualization engine 240. The system 200 also includes a digital audio instrument 250 in communication with the computer over an audio channel 260.

The digital audio instrument 250 can be an electronic musical instrument, or a source of audio input, such as digital audio input that is discretized. Thus, the audio signals can be represented as a discrete quantity. This discretized representation of the digital audio input can also be from an electronic source, such as an electronic memory, register, non-transitory electronic storage medium, EEPROM, ROM or other suitable memory. For example, the digital audio instrument 250 can be an electronic musical keyboard, digital piano, music synthesizer, or any other suitable electronic musical instrument operable to generate digital audio discretized output compliant with the Musical Instrument Digital Interface (MIDI) standard (or protocol). It can also be an electronic memory that stores an electronic version, or electronic representation of musical notes and/or signals. The digital audio signals may represent or correspond to musical notes of a musical instrument, song or musical composition. These representations of musical notes are used as input to the form visualization engine 240, as described herein.

The audio channel 260 allows the computer 270 to receive output from the digital audio instrument 250 as digital audio discretized input. The audio channel 260 can include one or more audio channels. For example, the audio channel can include a MIDI channel 0, a MIDI channel 1, and a time control channel (not shown). The MIDI channel 0 can transmit MIDI instrument output from the digital audio instrument. Optionally, the MIDI channel 1 can transmit MIDI foot pedal output from the digital audio instrument 250. Further optionally, the time control channel can transmit a measure of time to facilitate sequential animation or sequential refinement of an initial spatial form. The MIDI channels use the MIDI standard, which can be implemented using either the MIDI library built into the Windows operating system or third-party MIDI libraries (e.g., MIDIUtil, Mido or OpenMIDIProject) for additional functionality and customization.

For example, the digital audio discretized input can be, for example, MIDI input received over a specific MIDI channel, where the MIDI input represents a musical note or a control instruction e.g., a MIDI foot pedal that changes qualities of the musical note. In some embodiments, the architectural form generation system 200 can receive the digital audio discretized input over a wired or wireless connection. For example, embodiments permit reception of the digital audio discretized input over a wireless connection in accordance with an Open Sound Control (OSC) protocol, which can be implemented through libraries such as TinyOSC and python-osc. The system converts the received MIDI input into an OSC value, for example from 0-127. In some embodiments, the received input is filtered so as to identify only the desired input, such as corresponding musical notes without any unrelated MIDI control or timing instructions, or other undesired artifacts. Alternatively, the desired input can be filtered to include only the corresponding control instructions without any unrelated musical notes, depending on the specific audio channel being analyzed (e.g., MIDI channel 0, MIDI channel 1, or the time control channel).

The form visualization engine, also referred to as architectural generator 240, may utilize processor 210 to execute instructions to generate a spatial form and/or an architectural form of the digital audio data signals from digital audio instrument 250. The form visualization engine 240 has adequate electronic storage capacity and adequate processing power to perform a transpose of input digital discretized audio signals into a spatial form and/or an architectural form of the input digital audio signals. In some embodiments, Autodesk Maya, Rhino and/or Autodesk Revit (i.e., tools), as instances of the form visualization engine 240 (shown in FIG. 2), can visually represent tonal intervals, for example, by linking or transforming them into Pythagorean triples. These tools can also create spatial and/or architectural forms that are either two-dimensional and/or three-dimensional. For example, Autodesk Maya enables users to visualize Pythagorean triples through 3D rendering and geometric transformations, including command functions that may incorporate 3D mirroring or Sub-Division sub-functions.

Additionally, the form visualization engine 240 may dynamically select a machine learning model structure, which may include a single model or a combination of machine learning models, for transforming the digital audio signals into data representative of some spatial and/or architectural form.

The form visualization engine 240 can select an appropriate machine learning model for performing sequential actions to generate the spatial and/or architectural form, which may be two-dimensional or three-dimensional. The model selected is used to generate a desired rendering of the spatial and/or architectural form of the digital audio input based at least in part on the digital audio signals received from source 250. The model selected can be based, at least in part, on the type of digital audio input from source 250 and/or characteristics of the digital audio instrument 250. The characteristics, or parameters, may include an octave, a musical note, a type of musical note, a bass level, a treble level, a volume level, a tempo, or other characteristic of the digital audio instrument 250. The characteristics, or parameters, of the digital audio instrument 250 determine the model selected and thus, the spatial and/or architectural form generated and output from the form visualization engine 240.

The form visualization engine 240 may avail any number of technologies to obtain the characteristics of digital audio signals. One example technology known as Open Sound Control (OSC), which has incorporated into its protocol the associated MIDI protocol, codifies the same characteristics except at a higher resolution than MIDI and provides additional characteristics regarding the digital audio signals and the music encoded therein. For simplicity, the following description of FIG. 2 will assume that the form visualization engine 240 receives a single OSC value for each musical note in a sequence of musical notes that is recorded in the digital audio signals. However, those skilled in art should appreciate that the form visualization engine 240 can also process multiple OSC values for a single musical note or handle a chord (e.g., a harmonic combination of two or more musical notes played, sounded or recorded together) by processing “Note On” messages for each individual musical note within a chord. This capability enables the form visualization engine 240 to manage and process complex musical notes, pieces, compositions or songs.

The form visualization engine 240 can determine a modeling root value and/or root note (or root) based on the received digital audio instrument 250, which may be discretized as previously described. For example, the spatial and/or architectural form generation performed by form visualization engine 240 can determine a modeling root value and/or root note based on the digital audio signal, which may be discretized, by converting received OSC value(s) (e.g., a string between 0-127) into an integer. In some embodiments, the first musical note in the sequence of musical notes may be assumed to be the root note. Alternatively, a sequence of musical notes may be analyzed and a lookup table (included in the Python or other suitable libraries) of musical scales or keys may be used to identify the root note, which then may influence the modeling root value.

For example, if the sequence of musical notes is in the musical scale of C major, the musical note “C” would be identified as the root note. The modeling root value may be directly or indirectly derived from the root note and function similarly to the root note (or root) in a musical scale, providing the center or reference for a spatial form and/or architectural form. The form visualization engine 240 can use the modeling root value as a starting point upon which the sequence of musical notes can be transformed into a spatial and/or architectural form. In this manner, the modeling root value as well as spatial and/or architectural features, attributes and parameters (or input parameters) can be used by the form visualization engine 240 to generate a spatial and/or architectural form of the digital audio instrument 250, linking musical characteristics (of the sequence of musical notes) to spatial and/or architectural forms or machine learning models.

The form visualization engine 240 may employ a trained machine learning model to map individual musical notes along a musical scale to respective branches of the Pythagorean (or Pythagoras) tree. In this manner, the musical notes themselves may guide the form visualization engine 240 in generating the spatial form and/or architectural form of the music encoded on the discretized digital audio instrument 250. Furthermore, the form visualization engine 240 may use the spatial form to assist in generating or guiding the creation of architectural forms, including derived architectural plans or designs for physical buildings (e.g., via a software plug-in).

In some embodiments, a past machine learning model may be scored based on how often it has been deemed “similar” with one or more recent models (e.g., based on the aggregate amount of time that a given past model's parameter confidence set overlapped with a recent model's confidence set). By using this approach, the form visualization engine 240 is able to build a library of the most useful machine learning models in the recent past, while removing less useful models from the repository 258 in order to save storage space. The form visualization engine 240 can identify a desired set of rendering models or spatial or architectural forms for the digital audio data, which may be accessed from digital audio instrument 250.

In another embodiment, the form visualization engine 240 may identify a corresponding root triple (e.g., a Pythagorean triple) in either two-dimensional or three-dimensional space. In some embodiments, the form visualization engine 240 may determine one or more musical notes (e.g., musical note C) and then, generate, from an initial two-dimensional square construct (e.g., a unit square), a layered geometric structure by inserting new squares into the initial square. If a root triple of (3,4,5) is mapped to the musical note, the root triple forms the cartesian coordinates for inserting a first square into the unit square. The geometric structure becomes layered with the new squares forming a top-most layer; over a number of iterations, the geometric structure grows in an equal number of layers. For each iteration, the form visualization engine 240 may determine the intersecting planes for the new squares based on one or more musical notes. In an example where the geometric structure is a Pythagorean tree or Pythagoras tree (e.g., a fractal), the intersecting planes form a right triangle according to the Pythagorean theorem. Depending on one or more spatial or architectural features, the form visualization engine 240 may select from a number of available intersecting planes a specific right triangle to represent a particular musical note.

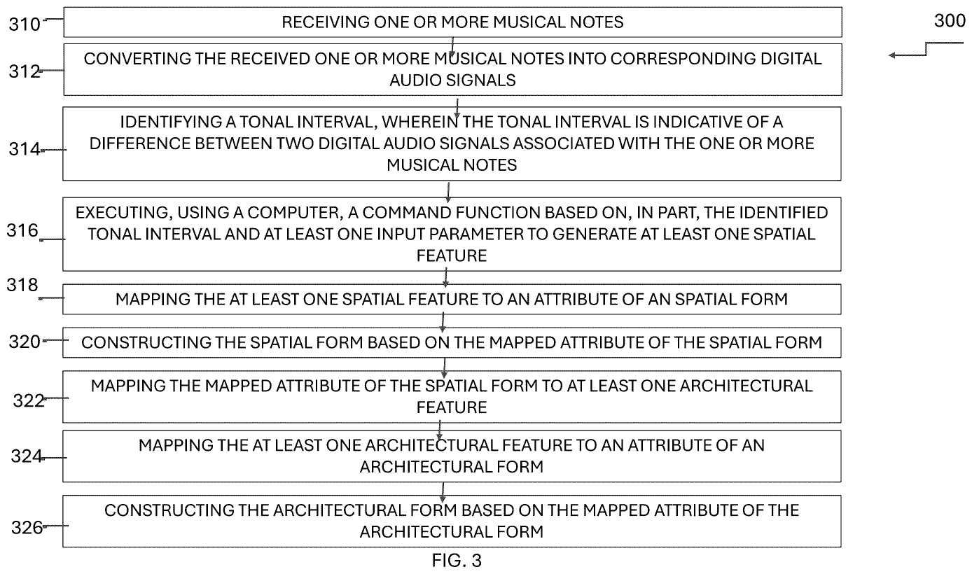

FIG. 3 illustrates a flowchart of a method 300 for generating an architectural form in accordance with an exemplary embodiment of the disclosure.

The architectural form generation system (shown in FIG. 2 as element 200) receives one or more musical notes input, 310. For example, the one or more musical notes input may be musical input representing discrete musical notes from a digital audio instrument, recording, musical composition, score, or other musical notes (shown in FIG. 2 as element 250) over an audio channel (shown in FIG. 2 as element 260). The audio input corresponds to digital audio signals received from a source such as electronic musical instrument, recording, and/or synthesized music, being previously recorded or being played by a user, such as from a musician playing an electronic musical keyboard that outputs digital audio in accordance with the MIDI standard/protocol.

The architectural form generation (shown in FIG. 2 as element 200) then converts the received one or more musical notes into corresponding digital audio signals, 312. For example, the architectural form generation can convert based on the one or more musical notes input into corresponding digital audio signals, i.e., by converting the received OSC value (e.g., a text string between 0-127) into an integer. This may be used in conjunction with the form visualization engine, shown in FIG. 2 as element 240. For example, a conversion engine can use an appropriate machine learning model and text conversion libraries e.g., in Python or other suitable libraries, to convert from one or more OSC value(s) received as a stream into a sequence of musical notes, an integer representing root note and an integer representing modeling root value suitable for use in the form visualization engine, shown in FIG. 2 as element 240. Additionally, the OSC value may be received as an integer value between 0-127. In some embodiments, a modeling root value may correspond to a spatial feature, initial construct of a spatial form, shape, geometric formation or geometry, to be built from the initial construct of the spatial form, which will later be used to generate the architectural form.

In some embodiments, musical notes are determined based, at least in part, on the received OSC values. In some embodiments, the received OSC value, which can range from 0 to 127 or 128 different values, may be converted or mapped into one of twelve musical notes on the musical scale or key, e.g., (1) A, (2) A ♯ (A sharp) or B♭ (B flat), (3) B, (4) C, (5) C ♯ or D♭, (6) D, (7) D ♯ or E♭, (8) E, (9) F, (10) F ♯ or G♭, (11) G, and (12) G ♯ or A♭. This conversion or mapping, referred to as musical pitch mapping, ensures a structured way to interpret the OSC values as musical notes.

For example, it is also an embodiment that received OSC values of 0, 11, 23, 35, 47, 60, 72, 84, 96, 108, or 120 are mapped to a C musical note, without necessarily distinguishing a specific octave for the C musical note. Not distinguishing or specifying a specific octave may permit flexibility in interpretation of the C musical note.

This musical pitch mapping approach may be further extended to other musical notes as well, with different OSC values assigned to each musical note in a musical scale. For example, in alternative embodiments, without necessarily specifying a particular octave for any musical note, the musical note “C” may correspond to received OSC values: 0, 12, 24, 36, 48, 60, 72, 84, 96, 108, and 120. Similarly, the OSC values for C ♯/D ♭ may be 1, 13, 25, 37, 49, 61, 73, 85, 97, 109, and 121. For musical note “D,” the OSC values may be 2, 14, 26, 38, 50, 62, 74, 86, 98, 110, and 122, while D ♯/E ♭ corresponds to 3, 15, 27, 39, 51, 63, 75, 87, 99, 111, and 123. The musical note “E” may be mapped to OSC values 4, 16, 28, 40, 52, 64, 76, 88, 100, 112, and 124.

Musical note “F” may be mapped or assigned to 5, 17, 29, 41, 53, 65, 77, 89, 101, 113, and 125, while F ♯/G ♭ may be mapped to 6, 18, 30, 42, 54, 66, 78, 90, 102, 114, and 126. The values for musical note “G” may be 7, 19, 31, 43, 55, 67, 79, 91, 103, 115, and 127, and for G ♯/A ♭, the corresponding OSC values may be 8, 20, 32, 44, 56, 68, 80, 92, 104, and 116. Musical note “A” may be mapped to 9, 21, 33, 45, 57, 69, 81, 93, 105, and 117, while A ♯/B ♭ may correspond to 10, 22, 34, 46, 58, 70, 82, 94, 106, and 118. Last, the OSC values for musical note “B” may be 11, 23, 35, 47, 59, 71, 83, 95, 107, and 119.

The architectural form generation (shown in FIG. 2 as element 200) then identifies a tonal interval, representing the difference between two digital audio signals associated with one or more musical notes, 314. Based on, in part, the identified tonal interval and at least one input parameter, the architectural form generation (e.g., a computer) executes a command function to generate at least one spatial feature, 316. The least one spatial feature, 316, is then mapped to an attribute of a spatial form, 318, which serves as the basis for constructing the spatial form, 320. The mapped attribute of the spatial form, 320, is then mapped to at least one architectural feature, 322. Then, the at least one architectural feature 322 is further mapped to an attribute of an architectural form, 324. Finally, the architectural form is constructed based on the mapped attribute of the architectural form 326.

A spatial form, for example as shown in FIG. 1 as element 100, can be constructed based, at least in part, on the musical notes, 310. In general, generation of the spatial form proceeds based on the musical notes along with one or more tonal intervals, and input parameters. An initial spatial form is generated based, at least in part, on the spatial features based on an executed command function. The generation can refine the initial spatial form based, at least in part, on audio channel inputs received via the audio channel, which is shown in FIG. 2 as element 260. The spatial form can be displayed, or output, or transmitted, as a two-dimensional representation or a three-dimensional representation, which will later be used to generate the architectural form. The architectural form may be physically realized using a two-dimensional printer, a three-dimensional printer, or rendered via a graphical user interface (GUI) or other suitable output or storage device. For three-dimensional representations, control instructions are generated for a three-dimensional printer by converting the refined architectural form into machine-readable formats, such as G-code or stereolithography (STL) files. These STL files define the geometry, material deposition paths, and printer-specific parameters, including layer height, extrusion speed, and print bed temperature. The control instructions ensure that the three-dimensional printer translates the architectural form or design into a physical structure or building. Output of the control instructions can also be visualized or manipulated using a GUI or stored for later use via a suitable storage device.

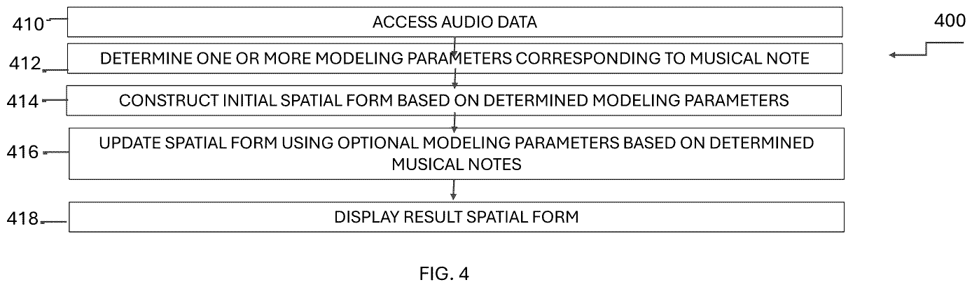

FIG. 4 illustrates a method 400 for generating an spatial form using music, musical notes and/or representations of musical notes, in accordance with an embodiment of the disclosure.

Audio data is accessed, 410. The architectural form system determines one or more modeling parameters corresponding to one or more determined musical notes, 412. These modeling parameters define characteristics that specify spatial features, such as shape, scale, or texture. For example, spatial features may include colors, planes, and layers of the spatial form. In some embodiments the architectural form system can assign an initial color, a spatial feature, corresponding to the one or more determined musical notes. For example, the system can determine that an initial color of green is assigned to all D musical note inputs. A user can change the properties of the spatial form rendering via user input to affect the color, dimensions, plane and/or layer as well as other user-defined parameters, spatial features, or user input values.

For example, the architectural generation system can assign an initial plane, an spatial feature, corresponding to the one or more determined musical notes. For example, a positive or negative axial orientation that is aligned with the x-, y-, or z-axis corresponding to the determined musical note, such an initial plane of the positive orientation along the x-axis being assigned to all C musical note inputs.

In some embodiments, an initial orientation angle, n spatial feature, can be assigned relative to the axis to musical notes having accidentals, such as an initial plane of 30 degrees relative to the negative y-axis being assigned to all F #musical note inputs. In some embodiments, an initial layer, a spatial feature, is assigned that corresponds to one or more determined musical notes.

An initial spatial form construct is generated based, at least in part, on a root note and one or more determined modeling parameters, 414. For example, an architectural form generator that generates a spatial form using the root note as a starting point. The root note can correspond to a spatial feature, initial construct (e.g., a square or a cube) and a geometric formation to be built on the initial construct. An updated spatial form can be constructed in layers where one or more polygons are positioned on the initial spatial form construct. These polygons can be of the same shape as the initial spatial form construct. The spatial form generator can use the root note to set one or more rules for the geometric formation, resulting in a final spatial form where each new layer positions a polygon along a plane. For example, the architectural form generator can generate a 3D polyform seed as input to the form visualization engine (shown in FIG. 2 as element 240) based, at least in part, on the root note. The architectural form generator can update the 3D polyform seed by using the musical notes to indicate a direction for the geometric formation, for example, by determining three-dimensional locations on the 3D polyform seed for positioning additional 3D polyforms. The architectural form generator can use the color spatial feature to determine an appropriate color for each additional 3D polyform.

Optionally, the architectural form generation system can update the geometry of the spatial form using one or more modeling parameters (e.g., spatial features) determined based, at least in part, on the one or more, musical notes, 416. In some embodiments, updates are made to the geometry by applying a 3D mirror transform to the initial spatial form construct, such as mirroring the initial 3D polyform seed about the axis and orientation angle defined by the 3D plane spatial feature.

The architectural form generation system displays and/or outputs the resulting spatial form, step 418. Optionally, a sequential animation or video illustrating the progression of transforms applied to the initial spatial form can be generated as well as a 3-d rendering of the progression of transforms, as well as a real-time audio output of the musical composition, or piece. Furthermore, the resulting spatial form can be translated into an architectural form, where the spatial features of the spatial form are assigned or mapped to the corresponding architectural features or attributes of the architectural form.

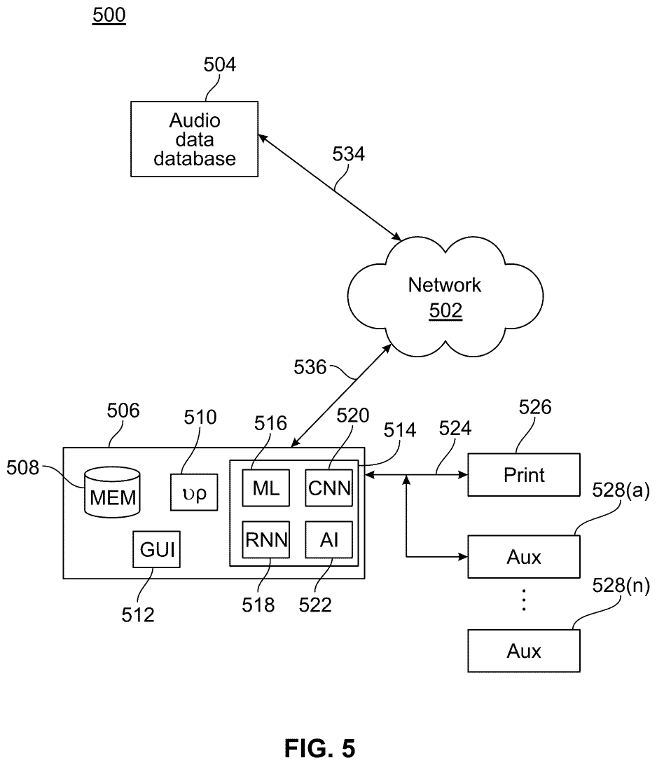

FIG. 5 illustrates a system 500 that may be used to generate a three-dimensional rendering of musical notes. The system 500 includes network 502, audio data storage device 504, user device 506, printer 526 and auxiliary devices 528(a) . . . (n), where “n” is any suitable number.

Network 502 may be a communication network (if wireless), such as the Internet, or any other interconnected computing devices and may be implemented using communication techniques such as Visible Light Communication (VLC), Worldwide Interoperability for Microwave Access (WiMAX), Long Term Evolution (LTE), Wireless Local Area Network (WLAN), Infrared (IR) communication; Public Switched Telephone Network (PSTN), radio waves, and other suitable communication techniques. The communication network 502 may allow ubiquitous access to shared pools of configurable system resources and higher-level services that can be rapidly provisioned with minimal management effort, often over the Internet, and rely on sharing resources to achieve coherence economies of scale, like a public utility. Alternatively, third-party clouds enable organizations to focus on their core businesses instead of expending resources on computer infrastructure and maintenance.

Network 502 permits bi-directional communication between audio data storage device 504, via bi-directional wired, or wireless communication channel 534, user device 506, via bi-directional wired, or wireless communication channel 536 as well as other network connected devices (not shown) via other suitable communication channels (not shown).

Network 502 may include a global system of interconnected computer networks that uses the Internet protocol (TCP/IP) to communicate between networks and devices. Network 502 may be a network of networks that may include one or more of private, public, academic, business, and government networks of local to global scope, linked by a broad array of electronic, wireless, optical networking, or other suitable wired of wireless networking technologies. The network 502 may carry a vast range of information resources and services, such as the inter-linked hypertext documents, applications, e-mail, file sharing and www web browsing capabilities.

Audio data storage device 504 may include a memory, such as electronic storage registers, ROM, RAM, EEPROM, non-transitory electronic storage medium, volatile memory, or non-volatile electronic storage media and/or other suitable computer memory. The computer readable storage medium may be, for example, but not limited to, an electronic, magnetic, optical, electromagnetic, infrared, or semiconductor system, apparatus, or device, or module or any suitable combination of the foregoing, including non-transitory computer readable media.

More specific examples (a non-exhaustive list) of the computer readable storage medium would include the following: a portable computer diskette, a hard disk, a random access memory (RAM), a read-only memory (ROM), an erasable programmable read-only memory (EPROM or Flash memory), a portable compact disc read-only memory (CD-ROM), a digital versatile disc (DVD), a Blu-ray Disc, an optical storage device, a magnetic tape, a Bernoulli drive, a magnetic disk, a magnetic storage device, a punch card, integrated circuits, other digital processing apparatus memory devices, or any suitable combination of the foregoing, but would not include propagating signals.

The audio data storage device 504 stores audio data that includes electronic representations of musical notes from musical instruments. This audio data may be representations of single notes, multiple notes, symphonies, musical scores, or any suitable musical composition. The audio data may be discretized i.e., represent or approximate, a quantity or series, using a discrete quantity or quantities. The audio data may also be recorded musical compositions or music being made in real time and provided to the transpose device, also referred to as transpose module, 514, as described herein.

User device 506 may be a PC, tablet, computer, or other suitable processing device and may include memory 508, processor 510, graphical user interface (GUI) 512, transpose device, or transpose module 514, printer 526 and auxiliary deices 528(a) . . . (n), where “n” is any suitable number.

For example, user device 506 may be a laptop, smartphone, PC, tablet or other electronic device that can do one or more of receive, process, store, display and/or transmit data. The user device 506 may have a connection, wired and/or wireless, to a network and/or directly to other electronic devices. The user device 506 may have a connection, wired and/or wireless, to network 502 and/or directly to other electronic devices (such as printer 526, auxiliary devices 528), via wired or wireless communication channels 536 and 514, respectively.

Memory 508 may be an electronic storage registers, ROM, RAM, EEPROM, non-transitory electronic storage medium, volatile memory, or non-volatile electronic storage media and/or other suitable computer memory. A computer readable storage medium may be, for example, but not limited to, an electronic, magnetic, optical, electromagnetic, infrared, or semiconductor system, apparatus, or device, or any suitable combination of the foregoing, including non-transitory computer readable media. The memory 508 may store any data used for the spatial form or architectural form rendering. This includes spatial features, architectural features, parameters, user input and other electronic data.

More specific examples (a non-exhaustive list) of the computer readable storage medium would include the following: a portable computer diskette, a hard disk, a random access memory (RAM), a read-only memory (ROM), an erasable programmable read-only memory (EPROM or Flash memory), a portable compact disc read-only memory (CD-ROM), a digital versatile disc (DVD), a Blu-ray Disc, an optical storage device, a magnetic tape, a Bernoulli drive, a magnetic disk, a magnetic storage device, a punch card, integrated circuits, other digital processing apparatus memory devices, or any suitable combination of the foregoing, but would not include propagating signals.

Processor 510 is any suitable processor with adequate processing power, which may include a CPU (central processing unit), integrated electronic circuit that performs operations to achieve a programmed task, and other instructions that may be accessed, or retrieved, from an operating system and executed. Program code for carrying out operations for aspects of the present disclosure may be generated by any combination of one or more programming language types, including, but not limited to any of the following: machine languages, scripted languages, interpretive languages, compiled languages, concurrent languages, list-based languages, object oriented languages, procedural languages, reflective languages, visual languages, or other language types. The program code may execute partially or entirely on the processor 510 and/or a processor associated with audio data database 504. Any remote computer may be connected through any type of network, including a local area network (LAN) or a wide area network (WAN), or the connection may be made to an external computer (for example, through the Internet using an Internet Service Provider).

GUI 512 is an interface that provides output to a user. It may also receive input from a user. The user input may include modifications to the color, plane, layer, size, proportions, and other desired criteria for the rendering that a user may wish to modify. The GUI 512 is a visual way of interacting with processor 510, memory 508 transpose module 514, printer 526 and auxiliary devices 528, using items such as windows, icons, and menus, used by most modern operating systems.

Transpose device, or transpose module, 514 is used to generate a representation, or rendering of musical notes, compositions, or other data from audio data, which may be accessed from audio data database 504. The transpose device 514 includes machine learning device, or module, (ML) 516, recurrent neural network (RNN) 518, convolutional neural network (CNN) 520 and artificial intelligence device, or module, (AI) 522. The transpose device 514 determines a modeling root value based at least in part on the construct; and generates an spatial form based at least in part on the root value and one or more spatial features.

Transpose device 514 operates in conjunction with memory 508, processor 510 and GUI 512. The transpose device 514 generates a rending of the audio data accessed from audio data storage device 504.

Machine learning device 516, is a computing device with adequate processing power and memory capacity to apply artificial intelligence (AI) 522 that helps AI systems learn and improve from experience. Indeed, successful machine learning training makes programs or AI solutions more useful by allowing the programs to complete the work faster and generate more accurate results. The process of machine learning works by forcing the system to run through its task over and over again, giving it access to larger data sets and allowing it to identify patterns in that data, all without being explicitly programmed to become “smarter.” As the algorithm gains access to larger and more complex sets of data, the number of samples for learning increases, and the system is able to discover new patterns that help it become more efficient and more effective. The first step for the machine learning model is to feed the model with a structured and large volume of data for training.

Convolutional neural network (CNN) device, or module, 520 has adequate processing power and memory to perform the convolutional neural network function and has a structure that includes a desired number of node layers, containing an input layer, one or more hidden layers, and an output layer. Each node, or artificial neuron, connects to another node or artificial neuron and has an associated weight and threshold. If the output of any individual node is above the specified threshold value, that node is activated, sending data to the next layer of the network. Otherwise, no data is passed along to the next layer of the network. Convolutional neural network 520 relies on training data to learn and improve accuracy over time.

Recurrent neural network (RNN) 518, can be any suitable model architecture, including stateful.

Use of transpose device 514, including machine learning 516, RNN 518, CNN 520 and AI 522 provides that after utilizing a large volume of data and configurations, the preferred model is selected. Supervised machine learning using neural networks may be performed to optimize weights of a particular model architecture to map features to targets, with the minimum amount of error. A variety of model representations may be used, including stateful, for example, recurrent neural networks, or RNNs 518, and stateless, for example, convolutional neural networks, or CNNs 520; in some embodiments, a mix of the two may be used, depending on design parameters.

The transpose module, or transpose device 514, operates in conjunction with the ML 516, RNN 516, CNN 520 and AI 522 and can periodically initiate a recent model and update the recent model along with the active model based on recently chosen actions and results of the active model. The transpose module or transpose device 514 evaluates the confidence sets of the model parameters and compares them to detect significant divergence. If a substantial divergence is identified, a replacement model is selected to address the deficiencies in the active model. This replacement model is then adopted as the new active model, using updated model parameters and an enhanced confidence set to improve actions.

In some embodiments, the replacement model may be selected from a library of past models, stored in memory 508. The replacement model may be selected based on a similarity with a current model. In some embodiments, past models that exceed a certain age, or operational life, or have not been recently used as the active model are removed from the library.

It is an embodiment of the disclosure that the transpose device, or transpose module 514 can occasionally or periodically retire models. This decision can be executed to preserve the best performing models. Alternatively, the decision can be based at least in part, or completely on user input. For example, either the transpose device 514 or a user can decide to maintain models that have been most active over a determined time period, for example, the prior 30 days, and retire or delete models that have not been used frequently. This modification in data can be achieved by a user inputting such criteria via GUI 512.

Printer 526 is operatively coupled to user device 506 via bi-directional wired or wireless communication channel 524. The printer 526 may be any suitable printer, such as a three-dimensional printer, which generates a three-dimensional rendering of the audio data, which may be a representation of musical notes, musical composition or other data that has been transposed, as described herein.

Auxiliary devices 528(a) . . . (n), where “n” is any suitable number, may be other printers, scanners, speakers, or other suitable output devices. Devices 528 may be used to output alternate representations of the audio data that has been transposed. For example, device 528 may be a conventional printer that prints a two-dimensional representation and printer 526 may be a three-dimensional printer that generates a 3-d rendering of the same audio data. Furthermore, another auxiliary device 528 could be speakers that provide an audio output of the audio data.

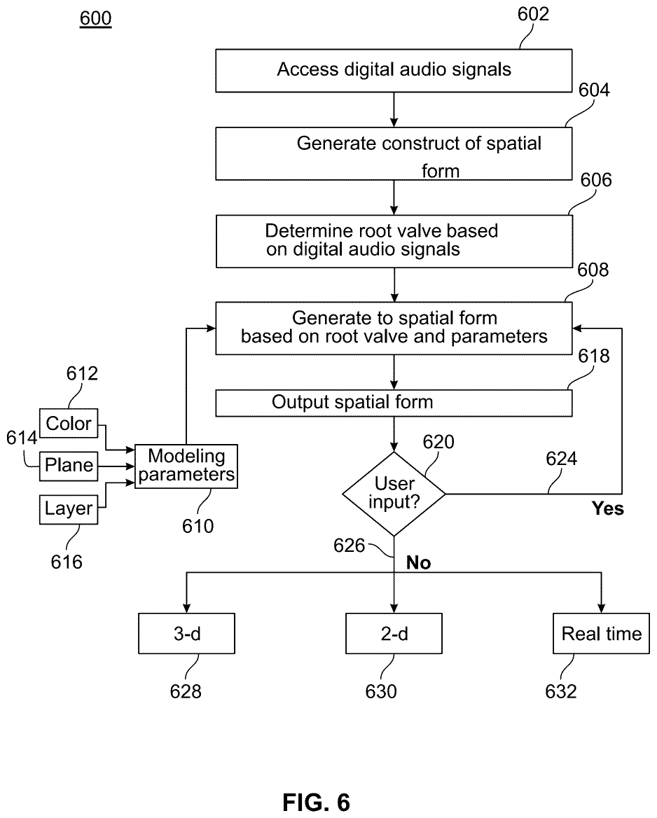

FIG. 6 illustrates a method 600 for generating a spatial form or architectural form rendering in accordance with an exemplary embodiment of the subject disclosure. The method shown in FIG. 6 is a computer-implemented method for generating a spatial form. The method may be stored on a computer-readable medium, as described herein, which may include electronic memory, register, non-transitory electronic storage medium, EEPROM, ROM or other suitable memory. The memory may be operated with one or more processors to execute code to perform the method 600. Digital audio signals are accessed, 602. A construct is generated, which is a construct of a spatial form based at least in part on the accessed digital audio signals, 604.

A root note is determined, which is based at least in part on the digital audio signals 606. A spatial form is generated, based at least in part on the root note and one or more spatial features, 608. The spatial features 610 may include color, 612, plane 614, and/or layer 616.

The spatial form is output, 618. A determination is made whether there is user input, 620. If so, “yes” 624 shows the generation of spatial form (or architectural form), 608 is repeated.

If there is no user input, “no” 626 shows a 3-dimensional rendering 628, 2-dimensional rendering 630 and/or real-time audio output 632 is provided.

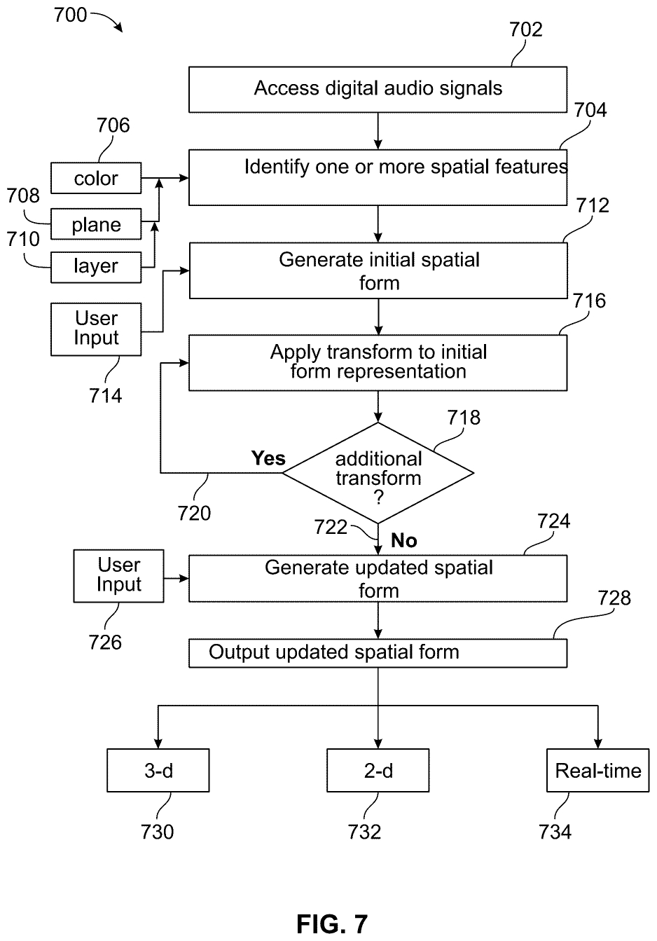

FIG. 7 illustrates a method 700 for generating an architectural form in accordance with an exemplary embodiment of the subject disclosure. The method 700 may be stored on a computer-readable medium, as described herein, which may include electronic memory, register, non-transitory electronic storage medium, EEPROM, ROM or other suitable memory and be accessed by a processor to execute code to perform the functionality of method 700. Digital audio discretized signals are accessed, 702. One or more spatial features are identified 704, each spatial feature corresponding to one or more musical notes. A spatial feature such as color, 706, plane, 708 and/or layer 710 may be used in the identification.

An initial spatial form of the digital audio discretized signals is generated 712. This initial spatial form is based, at least in part, on the digital audio discretized signals and the one or more spatial features. User input 714, may also be used in the generation. One or more transforms are applied to the initial spatial form, 716.

A determination is made whether there are additional transforms to be applied, 718. If so, “yes” 720 shows the application of one or more transforms, 716 is repeated.

If there are no additional transforms to be applied, “no” 722 shows an updated spatial form, or rendering is generated 724. User input may also be provided 726.

The updated spatial form is output 728. This output may be in any or all of a 3-dimensional rendering 730, a 2-dimensional rendering 732 and/or real-time audio output 734.

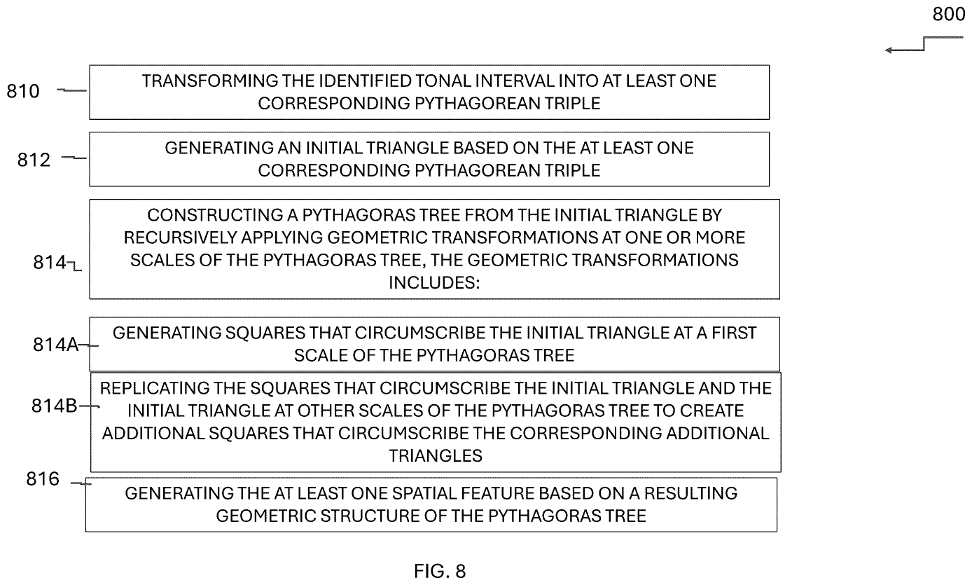

FIG. 8 illustrates a method 800 for generating a spatial form using music, musical notes and/or representations of musical notes, in accordance with an embodiment of the subject disclosure.

In some embodiments, one or more digital audio signals are received. The one or more digital audio signals are converted into one or more Musical Instrument Digital Interface (MIDI) messages, using the architectural form system.

In some embodiments, the one or more MIDI messages are processed to determine one or more tonal intervals. The one or more MIDI messages, mapped to the twelve musical notes on the musical scale, may be represented and processed using a music theory tool, known as the Circle of Fifths. Those skilled in the art should appreciate that the Circle of Fifths (implemented as a circle of fifths function) shows the relationships among the twelve musical notes on the musical scale and aids in the identification of tonal intervals within the sequence of received musical notes. Additionally, those skilled in the art may use other music theory tools to process the MIDI messages and analyze determined tonal intervals based on different theoretical frameworks (e.g., Circle of Fourths, Intervallic Matrix or Tonnetz).

The Circle of Fifths may be used in conjunction with the root note, which serves as the starting point or reference musical note, ensuring that tonal intervals and relationships are mapped to the correct musical scale. Additionally, the Circle of Fifths may receive musical notes as OSC values or MIDI message values as described above and adjust these inputs based on the root note.

Additionally, the Circle of Fifths organizes the twelve musical notes about the tonal interval or frequency ratio (3:2) of a perfect fifth. Each step (or a move between two musical notes) clockwise around the Circle of Fifths represents an ascend (or rise) by a perfect fifth (e.g., C→G). Mathematically, each step clockwise corresponds to multiplying the pitch frequency of the initial musical note by the perfect fifth's frequency ratio (3:2). For example, starting with the root note of “C,” having a pitch frequency (264 Hz), results in the musical note “G” (396 Hz) when moving clockwise.

Conversely, each step counterclockwise represents a descend by a perfect fifth or ascend by a perfect fourth (e.g., C→F). Mathematically, each step counterclockwise corresponds to dividing by the perfect fifth's frequency ratio (3:2). This operation is approximate to multiplying by frequency ratio (3:4), representing the frequency ratio (4:3) for a perfect fourth. For instance, starting with the root note C (264 Hz) results in the musical note F (176 Hz). Alternatively, multiplying the pitch frequency of the root note, C, by the perfect fourth's frequency ratio (3:4), gives approximately the pitch frequency of (198 Hz), which is close to the musical note F and may be considered as such.

Common tonal intervals, as described by their mathematical relationships, also correspond with movements around the Circle of Fifths with the root note providing the foundation or anchor for these movements. These include, but not limited to, the following: octave (2:1), where one musical note's pitch frequency is double the other, such as A4 (440 Hz) and A5 (880 Hz); perfect fifth (3:2), a consonant sound, as in C (264 Hz) and G (396 Hz); perfect fourth (4:3), as in G (396 Hz) and C (528 Hz); major third (5:4), as in C (264 Hz) and E (330 Hz); minor third (6:5), as in C (264 Hz) and Eb (316.8 Hz). Larger intervals, like the major sixth (5:3) and minor sixth (8:5), as in C (264 Hz) and A (440 Hz) or A♭ (352 Hz) and C (528 Hz), respectively. Smaller steps, such as the major second (9:8) and minor second (16:15), as in C (264 Hz) and D (297 Hz) or C (264 Hz) and C ♯ (281.6 Hz), respectively.

The one or more tonal intervals are transformed into at least one corresponding Pythagorean triple, 810. These tonal intervals or frequency ratios may be linked or mapped (i.e., transformed) to mathematical structures such as Pythagorean triples. To map or transform a sequence of two tonal intervals to a Pythagorean triple, consider how successive tonal intervals or frequency ratios align with the integer proportions in a Pythagorean triple. For example, start with a perfect fourth (4:3), followed by a major third (5:4) applied to a pitch frequency (90 Hz) for an initial musical note F #/Gb. When these tonal intervals or frequency ratios are combined, the resulting frequency ratio is 4/3×5/4=20/12. This mathematical relationship may be mapped or linked to correspond to the side lengths of the Pythagorean triple (9, 12, 15), when scaled by a factor of 10. The smallest side, 9, represents the pitch frequency of the initial musical note F #/Gb, such as 90 Hz. The second side, 12, corresponds to a frequency one perfect fourth (4:3 ratio) above the pitch frequency of the initial musical note, calculated as 90×4/3=120 Hz. The largest side, 15, represents the final pitch frequency corresponding to one major third above the intermediate pitch frequency (120 Hz), calculated as 120×5/4=150 Hz. Applying the perfect fourth (4:3 ratio) and major third (5:4 ratio), the final pitch frequency is 90×4/3×5/4=150 Hz.

An example of using musical pitch mapping for tonal intervals involves the conversion of OSC (Open Sound Control) values into musical notes, which are then utilized to define the tonal intervals. For instance, if an OSC value of 42 is mapped to the musical note D (the sixth note in the musical scale), and an OSC value of 57 is mapped to F #(the tenth note), the interval between these musical notes corresponds to a perfect fourth (4:3). Similarly, mapping an OSC value of 64 to A (the first note in the following octave) creates a major third (5:4) interval above F #. Using these mapped musical notes, the tonal intervals then may be combined and linked to a Pythagorean triple. Starting with the mapped pitch frequency for D as 90 Hz, the perfect fourth interval raises the frequency to 120 Hz (D to F #), and the subsequent major third interval increases it to 150 Hz (F #to A). This example sequence aligns with the scaled Pythagorean triple (9, 12, 15), showing how musical pitch mapping can integrate with tonal intervals to connect musical structures to mathematical representations.

Optionally, the tonal intervals within a sequence can be mapped to Pythagorean triples. For example, in a sequence of twelve tonal intervals, a perfect fourth occurs three (3) times, a perfect fifth occurs four (4) times and a major third occurs five (5) times. These frequencies may be mapped or linked to the side lengths of the Pythagorean triple (3, 4, 5). Optionally, a musical note may be mapped or linked directly to a Pythagorean triple. For example, the musical note C may directly correspond to the Pythagorean triple (3, 4, 5). Overall, the above examples demonstrate how the frequency ratios defining tonal intervals mirror the proportional relationships found in mathematical structures such as Pythagorean triples. Those skilled in art should appreciate that these are example approaches, and other approaches for transforming, linking and mapping tonal intervals to such mathematical structures are contemplated.

An initial triangle based on the at least one corresponding Pythagorean triple is generated, 812. A Pythagoras tree from the initial triangle by recursively applying geometric transformations at one or more scales of the Pythagoras tree is constructed, 814. The geometric transformations further include sub-method steps 814A, 814B. Squares that circumscribe the initial triangle at the first scale of the Pythagoras tree are generated, 814A. The squares that circumscribe the initial triangle and the initial triangle at other scales of the Pythagoras tree to create additional squares that circumscribe the corresponding additional triangles are replicated, 814B. A spatial form can be generated based on one or more tonal intervals, corresponding Pythagorean triples, and a Pythagoras tree, for example. This can be accomplished by an architectural form generator that generates a spatial form, or form, using a Pythagorean triple as a starting point. The Pythagorean triple defines an initial triangle and a Pythagoras tree (e.g., a fractal constructed from squares and right triangles) is constructed from the initial triangle recursively applying geometric transformations at one or more scales (or layers or branches) of the Pythagoras tree. An updated spatial form (because of the geometric structure of the Pythagorean tree) can be built or evolved layer-by-layer (or scale-by-scale), where additional triangles and squares are positioned relative to the initial triangle. For example, if the initial triangle is defined by the Pythagorean triple (3, 4, 5), its sides measure 3 and 4 units, with a hypotenuse of 5 units. Three squares are then generated to circumscribe the first triangle: the first square, with sides of 3 units, aligns with the base of the triangle. The second square, with sides of 4 units, aligns with the triangle's height. The third square, with sides of 5 units, aligns with the hypotenuse.

The process for constructing or building the spatial form (or Pythagoras tree) repeats recursively. At each layer or scale of the recursion, new triangles are replicated and generated following the same pattern. These new triangles may be rotated and resized through geometric transformations, and their sides form the boundaries for new squares that circumscribe them, resulting in a fractal-like structure. It should be appreciated that each new triangle is smaller than its predecessor but retains the proportionality and geometric relationships established by the initial triangle. Additionally, it is important to recognize that new triangles may be generated using tonal intervals distinct from the original tonal interval(s) and the corresponding Pythagorean triple that defined the initial triangle.

A spatial feature based on a resulting geometric structure of the Pythagoras tree is generated, 816. In some embodiments, 3D modeling tools such as Autodesk Maya and Rhino (serving as instances of element 240 in FIG. 2) can visually represent tonal intervals transformed into Pythagorean triples. Autodesk Maya, for example, allows users to visualize Pythagorean triples through 3D rendering and geometric transformations, including commands like 3D mirroring and the Sub-Division function. By leveraging Python scripting or Maya Embedded Language (MEL), users can define the vertices of triangles representing Pythagorean triples (e.g., 9, 12, 15) and connect them to form right triangles in a 3D environment. For instance, a script can specify coordinates for triangle vertices, such as (0, 0, 0), (9, 0, 0), and (9, 12, 0) and connect these points to construct the triangle in 3D space.

Beyond static visualization, Autodesk Maya allows for dynamic transformations like scaling or rotation to demonstrate proportional relationships among these Pythagorean triples. For instance, scaling the Pythagorean triple (3, 4, 5) by a factor of 2 creates the sequence (6, 8, 10). Visualization layers, such as color coding or overlays, can represent corresponding Pythagorean triple (e.g., 3:4:5). In Maya, the user could import the 3D right triangle or related geometric forms and use transformations like rotations and scaling to create dynamic spatial features such as spiraling staircases, vaulted ceilings, or repetitive geometric patterns for decorative facades. Color coding can also represent key harmonic relationships between musical notes and linked Pythagorean triples as visual motifs.

Similarly, Rhino can also be used to visualize Pythagorean triples and their geometric relationships through Rhino's Grasshopper plugin. Users can create parametric models to generate and manipulate right triangles based on Pythagorean triples such as (3, 4, 5). In Rhino with the Grasshopper plugin, a user can define the vertices (3, 4, 5) of a triangle as parametric points, for example at coordinates (0,0,0), (3,0,0), and (0,4,0). These points represent the geometric proportions of the 3:4:5 relationship, forming a right triangle. The user can then extrude this shape into 3D space to create the basis for a pavilion structure, such as a curved roof, stepped amphitheater, or supporting trusses (e.g., digital models or geometric representation). Those skilled in art should appreciate that although the above illustrations are described as using triangles the use of other geometries such as polygons and Non-Uniform Rational B-Splines (NURBS) surfaces are contemplated.

In some embodiments, an Autodesk Maya plug-in may be used to export spatial forms created in Autodesk Maya to Autodesk Revit, supporting formats such as Filmbox (FBX), Wavefront (.obj), and Standard ACIS Text (SAT or ACIS). Autodesk Revit is a building information modeling (BIM) software used by architects, engineers, and professionals to design, plan and manage building projects. This Autodesk Maya plug-in allows musician-architects to use Autodesk Maya (serving as an instance of element 240 in FIG. 2) to generate spatial forms and then transfer them into Autodesk Revit using as an architectural form for further architectural planning and documentation (e.g., architectural plans). Similarly, a Rhino Grasshopper plug-in may be used to export spatial forms to Autodesk Revit or used directly in Rhino 3D or any similar software applications for architectural form visualization.

The functions performed in the processes and methods described above may be implemented in differing order. Furthermore, the outlined steps and operations are only provided as examples. Some of the steps and operations may be optional, combined into fewer steps and operations, or expanded into additional steps and operations without detracting from the disclosed embodiments' essence.

Some embodiments of the disclosure may be described as a system, method, apparatus, or computer program product. Accordingly, embodiments of the disclosure may take the form of an entirely hardware embodiment, an entirely software embodiment (including firmware, resident software, micro-code, etc.) or an embodiment combining software and hardware aspects that may all generally be referred to herein as a “circuit,” “device,” “module” or “system.” Furthermore, aspects of the disclosure may take the form of a computer program product embodied in one or more computer readable storage media, such as a non-transitory computer readable storage medium, having computer readable program code embodied thereon.

Modules and/or devices may also be implemented in software for execution by various types of processors. An identified module of executable code may, for instance, comprise one or more physical or logical blocks of computer instructions, which may, for instance, be organized as an object, procedure, or function. Nevertheless, the executables of an identified module need not be physically located together but may comprise disparate instructions stored in different locations which, when joined logically, or operationally, together, comprise the module and achieve the stated purpose for the module.

Indeed, a module of executable code may be a single instruction, or many instructions, and may even be distributed over several different code segments, among different programs, and across several memory devices. Similarly, operational data may be identified and illustrated herein within modules and may be embodied in any suitable form and organized within any suitable type of data structure. The operational data may be collected as a single data set or may be distributed over different locations including over different storage devices, and may exist, at least partially, merely as electronic signals on a system or network. The system or network may include non-transitory computer readable media. Where a module or portions of a module are implemented in software, the software portions are stored on one or more computer readable storage media, which may be a non-transitory media.

Any combination of one or more computer readable storage media may be utilized. A computer readable storage medium may be, for example, but not limited to, an electronic, magnetic, optical, electromagnetic, infrared, or semiconductor system, apparatus, or device, or any suitable combination of the foregoing, including non-transitory computer readable media.

Some embodiments of the disclosure may be described as a system, method, apparatus, or computer program product. Accordingly, embodiments of the disclosure may take the form of an entirely hardware embodiment, an entirely software embodiment (including firmware, resident software, micro-code, etc.) or an embodiment combining software and hardware aspects that may all generally be referred to herein as a “circuit,” “device” “module” or “system.” Furthermore, aspects of the disclosure may take the form of a computer program product embodied in one or more computer readable storage media, such as a non-transitory computer readable storage medium, having computer readable program code embodied thereon. Aspects of the subject disclosure can be implemented in a variety of technical exemplary use cases. The following use case is merely exemplary and is not intended to limit the scope of the subject disclosure.

In exemplary use cases, a musician-architect provides or receives musical notes or musical data, e.g., from a Katy Perry song, such as “Firework” to or to provide the system for generating architectural forms. The system processes each musical note in the song's sequence by converting the musical note into a corresponding digital audio signal or discretized digital audio signal using a protocol or library such as MIDI (Musical Instrument Digital Interface) or OSC (Open Sound Control). The corresponding digital audio signal (or MIDI data) captures parameters like pitch (frequency), duration (time length), and amplitude of each musical note.

The system then analyzes or identifies tonal intervals using the Circle of Fifths by calculating the differences (or OSC values) between digital audio signals relative to a root note. The root note serves as the starting point or reference musical note. For example, the tonal interval between the musical notes “A4” and “C5” is a minor third, while “C5” to “E5” is a major third. These identified tonal intervals along with the root note serve as the basis for generating one or more spatial features for one or more spatial forms.

Next, based on an input parameter or a musician-architect setting, the system determines the appropriate command function (e.g., programming logic) to execute for the identified tonal intervals. If the input parameter specifies using identified tonal intervals to determine window sizes of a set of windows or other architectural features, the system proceeds as follows. The system selects the appropriate command function containing the relevant logic (e.g., Python script), which maps the one or more identified tonal intervals to spatial features (e.g., primitives, polygons, or shapes). For instance, a minor third interval may correspond to a small square (window) shape, a major third to a tall rectangular (window) shape, and a perfect fifth to a wide horizontal (window) shape. These spatial features will be mapped to architectural features such as windows and their dimensions.

The system then maps the determined spatial features to attributes of a spatial form and renders the spatial form in either two-dimensional or three-dimensional space on a computer screen or display. The rendered output includes attributes such as a small square (window) shape, a tall rectangular (window) shape, and a wide horizontal (window) shape positioned on a wall shape within the spatial form. Once the musician-architect is approves the rendering of the spatial form, the system outputs the spatial form in a format that corresponds to an architectural form. This means that the spatial features of the spatial form are mapped to the architectural features (e.g., windows, doors, panels, dimensions, styles, shapes, colors) and then attributes of the architectural form. Continuing the above example, the small square (window) shape, tall rectangular (window) shape, and wide horizontal (window) shapes in the spatial form are translated or mapped into corresponding architectural features or counterparts, a small square window, a tall rectangular window, and a wide horizontal window-within the architectural form. The system then renders the architectural form in either two-dimensional or three-dimensional space on a computer screen or display. The musician-architect using the system may proceed to transform the architectural form into one or more physical structures via through construction or 3D printing or represented through technical outputs or documentation such as floor plans, ceiling plans, structural plans and elevations (i.e., architectural plans).

If the input parameter specifies using identified tonal intervals to determine the placement or spacing between architectural features, such as the placement or spacing of the six windows along an architectural form or the wall thereof, the system proceeds accordingly. The system selects the appropriate command function containing the logic (e.g., Python script), which maps the one or more identified tonal intervals to spatial features (e.g., primitives, polygons, or shapes). For instance, a larger tonal interval, such as a perfect fifth, could correspond to wider spacing between window shapes, creating more visual separation. Conversely, a smaller interval, for instance a minor third, would result in closer spacing, creating a more compact arrangement viewable in the spatial form (and the architectural form). As a result, the placement or spacing of the window shapes would reflect the rhythm and flow of the “Firework” song's sequence. These spatial features are then mapped to the architectural features or attributes (as described earlier with window sizes) in the architectural form.

Similarly, if the input parameter specifies using identified tonal intervals to determine the colors representing architectural features, the system processes the tonal intervals to map them to specific colors. These colors are assigned to blocks or panels representing various architectural features or attributes for an architectural form. The system proceeds accordingly. The system selects the appropriate command function (e.g., Python script), which maps the one or more identified tonal intervals to spatial features (e.g., colors). For example, a minor third interval might correspond to the color red, a major third to green and a perfect fifth to orange. These spatial features are then mapped (as described earlier with window sizes) to the architectural features, such as the colors on blocks or panels in the architectural form.

If the input parameter specifies using identified tonal intervals to determine the structure of a building based on Pythagorean triples, the system follows a similar process. The system selects the appropriate command function (e.g., Python script), which maps the one or more identified tonal intervals to spatial features derived from Pythagorean triples. For instance, tonal intervals are mapped to Pythagorean triples. In a sequence of twelve tonal intervals identified in the Katy Perry song, a perfect fourth appears three times, a perfect fifth appears four times and a major third appears five times. These frequencies may be mapped or linked to the side lengths of the Pythagorean triple (3, 4, 5). Alternatively, a musical note may be mapped or linked directly to a Pythagorean triple. For example, the musical note C may directly correspond to the Pythagorean triple (3, 4, 5). Using at least one corresponding Pythagorean triple, the system generates an initial triangle and constructs a Pythagoras tree by recursively applying geometric transformations at various scales. A spatial form is then created based on tonal intervals, Pythagorean triples, and the Pythagoras tree. The system processes this spatial form, transforming it into an architectural form (as described earlier with window sizes). Ultimately, these spatial features derived from the Pythagoras tree are mapped to architectural features or attributes within the architectural form.

In another example, if the input parameter specifies using identified tonal intervals to determine the structure of a building based on a 3D polyform seed, the system proceeds accordingly. The system selects the appropriate command function (e.g., a Python script utilizing 3D polyforms), which maps the one or more identified tonal intervals to spatial features. For instance, a tonal interval may serve as a 3D polyform seed, which is input into the system based on a modeling root value. The system refines the 3D polyform seed by using other tonal intervals (or the modeling root value) derived from musical notes to determine the geometric formation's direction. The system identifies three-dimensional locations on the 3D polyform seed where additional 3D polyforms should be placed. The system also assigns colors to the newly added polyforms based on their corresponding tonal intervals. Additionally, the system can modify the geometry of a spatial form based on 3D polyforms by incorporating spatial features, such as transformations that adjust the spatial form's structure. Geometry updates involve applying a 3D mirror transformation (e.g., a transformation) to the initial construct of the spatial form or initial spatial form. For example, the system may mirror the original 3D polyform seed along an axis (e.g., X, Y, Z) and orientation angle (e.g., 90 degrees) defined by a 3D plane spatial feature. Mirroring can occur along three axes in both positive and negative directions (+X, +Y, +Z, −X, −Y, −Z), yielding six controllable mirroring variables that the musician-architect can adjust, or which can be based on the identified tonal intervals. Further refinement of the mirroring is possible by incorporating 90-degree rotations (i.e., orientation angles) between these axes in both positive and negative directions, providing a total of 12 controllable mirroring variables. Finally, the refined spatial features of the spatial form, derived from 3D polyforms, are mapped to architectural features or attributes in the architectural form (as described earlier with window sizes). It should be noted that the system can perform one or more of the processes described above concurrently or sequentially, depending on the input parameters provided by the musician-architect.

It will be appreciated by those skilled in the art that changes could be made to the various exemplary embodiments described above without departing from the broad inventive concept thereof. It is to be understood, therefore, that the disclosure is not limited to the particular aspects and embodiments disclosed, but it is intended to cover modifications within the spirit and scope of the subject disclosure as disclosed above and appended claims.

I claim:

1. A method of generating architectural forms comprising:
receiving one or more musical notes;
converting the received one or more musical notes into corresponding digital audio signals;
identifying a tonal interval, wherein the tonal interval is indicative of a difference between two digital audio signals associated with the one or more musical notes;
executing, using a computer, a command function based on, in part, the identified tonal interval and at least one input parameter to generate at least one spatial feature;
mapping the at least one spatial feature to an attribute of a spatial form;
constructing the spatial form based on the mapped attribute of the spatial form;
mapping the mapped attribute of the spatial form to at least one architectural feature;
mapping the at least one architectural feature to an attribute of an architectural form; and
constructing the architectural form based on the mapped attribute of the architectural form.

2. The method of claim 1, wherein identifying the tonal interval further comprises:
designating a first digital audio signal from the corresponding digital audio signals as a root note;
applying a circle of fifths function with the root note as input to process the corresponding digital audio signals; and
determining the one or more tonal intervals based on the processed corresponding digital audio signals.

3. The method of claim 2, wherein the least one input parameter is specified to determine one or more sizes of a set of architectural features.

4. The method of claim 2, wherein the least one input parameter is specified to determine one or more colors represent a set of architectural features.

5. The method of claim 2, wherein the least one input parameter is specified to determine a set of architectural features, the set of architectural features are based on Pythagorean triples.

6. The method of claim 2, wherein the least one input parameter is specified to determine a set of architectural features, the set of architectural features are based on a 3D polyform seed.

7. The method of claim 5, wherein executing, using a computer, the command function based on, in part, the identified tonal interval and the at least one input parameter to generate the at least one spatial feature further comprises:
transforming the identified tonal interval into at least one corresponding Pythagorean triple;
generating an initial triangle based on the at least one corresponding Pythagorean triple;
constructing a Pythagoras tree from the initial triangle by recursively applying geometric transformations at one or more scales of the Pythagoras tree, the geometric transformations include:
generating squares that circumscribe the initial triangle at a first scale of the Pythagoras tree, and
replicating the squares that circumscribe the initial triangle and the initial triangle at other scales of the Pythagoras tree to create additional squares that circumscribe the corresponding additional triangles; and
generating the at least one spatial feature based on a resulting geometric structure of the Pythagoras tree.

8. The method of claim 1, wherein the architectural form is an architectural plan.

9. The method of claim 1, wherein the architectural form is a digital model.

10. The method of claim 1, wherein the architectural form comprises two-dimensional data.

11. A computer-implemented method for generating architectural forms, the method comprising:
receiving one or more musical notes;
converting the received one or more musical notes into corresponding digital audio signals;
identifying a tonal interval, wherein the tonal interval is indicative of a difference between two digital audio signals associated with the one or more musical notes;
executing, using a computer, a command function based on, in part, the identified tonal interval and at least one input parameter to generate at least one spatial feature;
mapping the at least one spatial feature to an attribute of an spatial form;
constructing the spatial form based on the mapped attribute of the spatial form;
mapping the mapped attribute of the spatial form to at least one architectural feature;
mapping the at least one architectural feature to an attribute of an architectural form; and
constructing the architectural form based on the mapped attribute of the architectural form.

12. The computer-implemented method of claim 11, wherein identifying the tonal interval further comprises:
designating a first digital audio signal from the corresponding digital audio signals as a root note;
applying a circle of fifths function with the root note as input to process the corresponding digital audio signals; and
determining the one or more tonal intervals based on the processed corresponding digital audio signals.

13. The computer-implemented method of claim 12, wherein the least one input parameter is specified to determine one or more sizes of a set of architectural features.

14. The computer-implemented method of claim 12, wherein the least one input parameter is specified to determine one or more colors represent a set of architectural features.

15. The computer-implemented method of claim 12, wherein the least one input parameter is specified to determine a set of architectural features, the set of architectural features are based on Pythagorean triples.

16. The computer-implemented method of claim 12, wherein the least one input parameter is specified to determine a set of architectural features, the set of architectural features are based on a 3D polyform seed.

17. The computer-implemented method of claim 15, wherein executing, using a computer, the command function based on, in part, the identified tonal interval and the at least one input parameter to generate the at least one spatial feature further comprises:
transforming the identified tonal interval into at least one corresponding Pythagorean triple;
generating an initial triangle based on the at least one corresponding Pythagorean triple;
constructing a Pythagoras tree from the initial triangle by recursively applying geometric transformations at one or more scales of the Pythagoras tree, the geometric transformations include:
generating squares that circumscribe the initial triangle at a first scale of the Pythagoras tree, and
replicating the squares that circumscribe the initial triangle and the initial triangle at other scales of the Pythagoras tree to create additional squares that circumscribe the corresponding additional triangles; and
generating the at least one spatial feature based on a resulting geometric structure of the Pythagoras tree.

18. The computer-implemented method of claim 11, wherein the architectural form is an architectural plan.

19. The computer-implemented method of claim 11, wherein the architectural form comprises two-dimensional data.

20. The computer-implemented method of claim 11, wherein the architectural form comprises three-dimensional data.
